(19) United States
(12) Patent Application Publication
(10) Pub. No.: US 2024/0258981 A1
(43) Pub. Date: Aug. 1, 2024

(54) Method Of Manufacturing Vibration Element

(71) Applicant: SEIKO EPSON CORPORATION, Tokyo (JP)

(72) Inventors: Osamu KAWAUCHI, Shiojiri (JP); Takashi YAMAZAKI, Shiojiri (JP); Takuro KOBAYASHI, Minowa (JP)

(21) Appl. No.: 18/426,460

(22) Filed: Jan. 30, 2024

(30) Foreign Application Priority Data
Jan. 31, 2023 (JP) 2023-012799

(51) Int. Cl. H03H 3/02; H03H 9/215

(52) U.S. Cl. CPC H03H 3/02; H03H 9/215; H03H 2003/026

(57) ABSTRACT

A method of manufacturing a vibration element includes: manufacturing, by wet etching, a piezoelectric substrate including a vibration element, a frame portion, and a coupling portion that couples the frame portion and the vibration element; and folding the vibration element at the coupling portion and separating the vibration element from the frame portion. In the manufacturing of the piezoelectric substrate by the wet etching, the coupling portion is formed with a first groove portion, and a first protruding portion and a second protruding portion. The first protruding portion has a first outer shape side that defines an outer shape of the coupling portion and a second outer shape side that defines a boundary between the first protruding portion and the first groove portion, and is formed in a shape in which a distance between the first outer shape side and the second outer shape side decreases as a distance from the outer shape side of the vibration element increases. The second protruding portion has a third outer shape side that defines the outer shape of the coupling portion and a fourth outer shape side that defines a boundary between the second protruding portion and the first groove portion, and is formed in a shape in which a distance between the third outer shape side and the fourth outer shape side decreases as a distance from the outer shape side of the vibration element increases.

### BACKGROUND

The present application is based on, and claims priority from JP Application Serial Number 2023-012799, filed Jan. 31, 2023, the disclosure of which is hereby incorporated by reference herein in its entirety.

### 1. Technical Field

The present disclosure relates to a method of manufacturing a vibration element.

### 2. Related Art

JP-A-2003-198303 discloses a method of manufacturing a piezoelectric vibrator element in which a desired outer shape of a piezoelectric vibrator element is processed by photoetching a quartz crystal wafer while leaving a coupling portion coupling to a frame portion, and the piezoelectric vibrator element is separated from the frame portion by folding the coupling portion. In JP-A-2003-198303, a recessed groove is formed in a coupling part of the coupling portion with the piezoelectric vibrator element, and an arc-shaped notch is formed in each corner portion at both ends of the coupling part in a width direction.

JP-A-2003-198303 is an example of the related art.

However, in the method of manufacturing a piezoelectric vibrator element disclosed in JP-A-2003-198303, the notch in the coupling part has an arc shape. Therefore, when the piezoelectric vibrator element is separated from the frame portion by folding the coupling portion, a breaking position may vary, and a remaining portion of the coupling portion remaining in the piezoelectric vibrator element after folding may become large.

### SUMMARY

A method of manufacturing a vibration element according to an aspect of the present disclosure includes:
manufacturing, by wet etching, a piezoelectric substrate including a vibration element, a frame portion, and a coupling portion that couples the frame portion and the vibration element; and
folding the vibration element at the coupling portion and separating the vibration element from the frame portion, in which
in the manufacturing of the piezoelectric substrate by the wet etching,
the coupling portion is formed with a first groove portion, and a first protruding portion and a second protruding portion at one surface of a first surface and a second surface which is in a front and rear relationship with the first surface, the first protruding portion and the second protruding portion being disposed at positions sandwiching the first groove portion and protruding from an outer shape side of the vibration element to which the coupling portion is coupled when viewed from a direction perpendicular to the one surface,
when viewed from the direction perpendicular to the one surface, the first protruding portion has a first outer shape side that defines an outer shape of the coupling portion and a second outer shape side that defines a boundary between the first protruding portion and the first groove portion, and is formed in a shape in which a distance between the first outer shape side and the second outer shape side decreases as a distance from the outer shape side of the vibration element to which the coupling portion is coupled increases, and the first outer shape side and the second outer shape side are formed to be inclined with respect to the outer shape side of the vibration element to which the coupling portion is coupled, and
when viewed from the direction perpendicular to the one surface, the second protruding portion has a third outer shape side that defines the outer shape of the coupling portion and a fourth outer shape side that defines a boundary between the second protruding portion and the first groove portion, and is formed in a shape in which a distance between the third outer shape side and the fourth outer shape side decreases as a distance from the outer shape side of the vibration element to which the coupling portion is coupled increases, and the third outer shape side and the fourth outer shape side are formed to be inclined with respect to the outer shape side of the vibration element to which the coupling portion is coupled.

### BRIEF DESCRIPTION OF THE DRAWINGS

FIG. 1 is a plan view schematically showing a vibration element.

FIG. 2 is a flowchart showing an example of a method of manufacturing a vibration element according to a first embodiment.

FIG. 3 is a plan view schematically showing a first surface side of a piezoelectric substrate.

FIG. 4 is a plan view schematically showing a coupling portion at the first surface side of the piezoelectric substrate.

FIG. 5 is a plan view schematically showing the coupling portion at the first surface side.

FIG. 6 is a plan view schematically showing the coupling portion at a second surface side.

FIG. 7 is a cross-sectional view schematically showing the coupling portion.

FIG. 8 is a diagram schematically showing a process of manufacturing the vibration element.

FIG. 9 is a diagram schematically showing the process of manufacturing the vibration element.

FIG. 10 is a diagram schematically showing the process of manufacturing the vibration element.

FIG. 11 is a diagram schematically showing the process of manufacturing the vibration element.

FIG. 12 is a diagram schematically showing the process of manufacturing the vibration element.

FIG. 13 is a diagram schematically showing the process of manufacturing the vibration element.

FIG. 14 is a diagram schematically showing the process of manufacturing the vibration element.

FIG. 15 is a diagram schematically showing the process of manufacturing the vibration element.

FIG. 16 is a diagram schematically showing the process of manufacturing the vibration element.

FIG. 17 is a diagram schematically showing the process of manufacturing the vibration element.

FIG. 18 is a diagram schematically showing the process of manufacturing the vibration element.

FIG. 19 is a diagram schematically showing the process of manufacturing the vibration element.

FIG. 20 is a diagram showing a step of separating the vibration element from a frame portion.

FIG. 21 is a plan view schematically showing the coupling portion at the first surface side.

FIG. 22 is a plan view schematically showing the coupling portion.

FIG. 23 is a cross-sectional view schematically showing the coupling portion.

FIG. 24 is a cross-sectional view schematically showing the coupling portion.

FIG. 25 is a diagram schematically showing the process of manufacturing the vibration element.

FIG. 26 is a diagram schematically showing the process of manufacturing the vibration element.

FIG. 27 is a plan view schematically showing the coupling portion.

FIG. 28 is a plan view schematically showing the coupling portion.

FIG. 29 is a cross-sectional view schematically showing the coupling portion.

FIG. 30 is a plan view schematically showing the coupling portion.

### DESCRIPTION OF EMBODIMENTS

Hereinafter, preferred embodiments of the present disclosure will be described in detail with reference to the drawings. The embodiments to be described below do not unduly limit contents of the present disclosure described in the claims. In addition, not all configurations to be described below are necessarily essential components of the present disclosure.

### 1. First Embodiment

### 1.1. Vibration Element

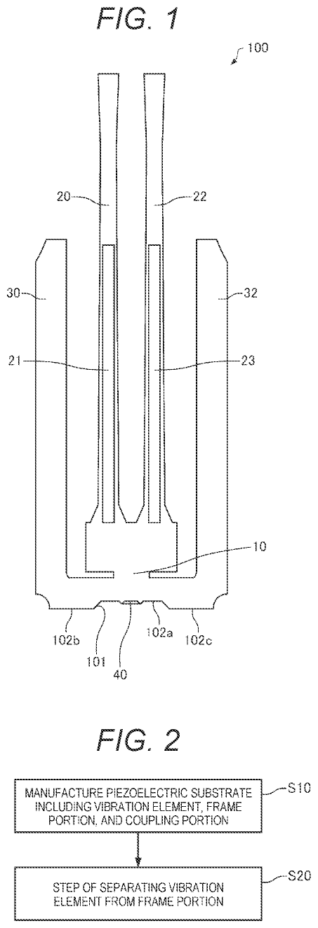

First, a vibration element manufactured by a method of manufacturing a vibration element according to a first embodiment will be described with reference to the drawings. FIG. 1 is a plan view schematically showing a vibration element 100 manufactured by the method of manufacturing the vibration element according to the first embodiment.

The vibration element 100 is a tuning fork type piezoelectric vibration element. As shown in FIG. 1, the vibration element 100 includes a base portion 10, a first vibration arm 20, a second vibration arm 22, a first support arm 30, and a second support arm 32.

The base portion 10, the first vibration arm 20, the second vibration arm 22, the first support arm 30, and the second support arm 32 are formed by patterning a piezoelectric substrate as described later. The piezoelectric substrate is made of a piezoelectric material such as quartz crystal, lithium tantalate, or lithium niobate. The piezoelectric substrate has a first surface and a second surface having a front and rear relationship with the first surface, and FIG. 1 shows the vibration element 100 at a first surface side.

The first vibration arm 20, the second vibration arm 22, the first support arm 30, and the second support arm 32 are coupled to the base portion 10. A folding trace 40 is formed in the base portion 10.

The folding trace 40 is a remaining portion of a coupling portion that couples a frame portion and the vibration element 100 and that remains in the vibration element 100 after the vibration element 100 is folded at the coupling portion in a process of manufacturing the vibration element. As shown in FIG. 1, the folding trace 40 protrudes from a first side 102a which is an outer shape side of the vibration element 100 to which the coupling portion is coupled. The first side 102a forms a bottom surface of a recessed portion 101. The recessed portion 101 is located between a second side 102b and a third side 102c which are outer shape sides of the vibration element 100. The folding trace 40 is located inside the recessed portion 101. That is, a distance between a tip end of the folding trace 40 and the first side 102a is smaller than a depth of the recessed portion 101.

The first vibration arm 20 and the second vibration arm 22 extend in a predetermined direction from the base portion 10. A long groove 21 is formed in the first vibration arm 20 at the first surface side. Although not shown, the long groove 21 is also formed in the first vibration arm 20 at a second surface side, similar to being formed at the first surface side. By forming the long groove 21 in the first vibration arm 20, the first vibration arm 20 is easily moved, and the first vibration arm 20 can be efficiently vibrated. Similar to the first vibration arm 20, long grooves 23 are formed in both surfaces of the second vibration arm 22.

Although not shown, drive electrodes for applying drive signals to the first vibration arm 20 and the second vibration arm 22 are formed on the first vibration arm 20 and the second vibration arm 22. By applying the drive signals to the first vibration arm 20 and the second vibration arm 22, the first vibration arm 20 and the second vibration arm 22 can be caused to perform flexural vibration by an inverse piezoelectric effect of the quartz crystal.

The first support arm 30 and the second support arm 32 are members for attaching the vibration element 100 to a package. By attaching the vibration element 100 to the package using the first support arm 30 and the second support arm 32, the first vibration arm 20, the second vibration arm 22, and the base portion 10 can be supported without being in contact with the package.

### 1.2. Method of Manufacturing Vibration Element

### 1.2.1. Flow of Method of Manufacturing Vibration Element

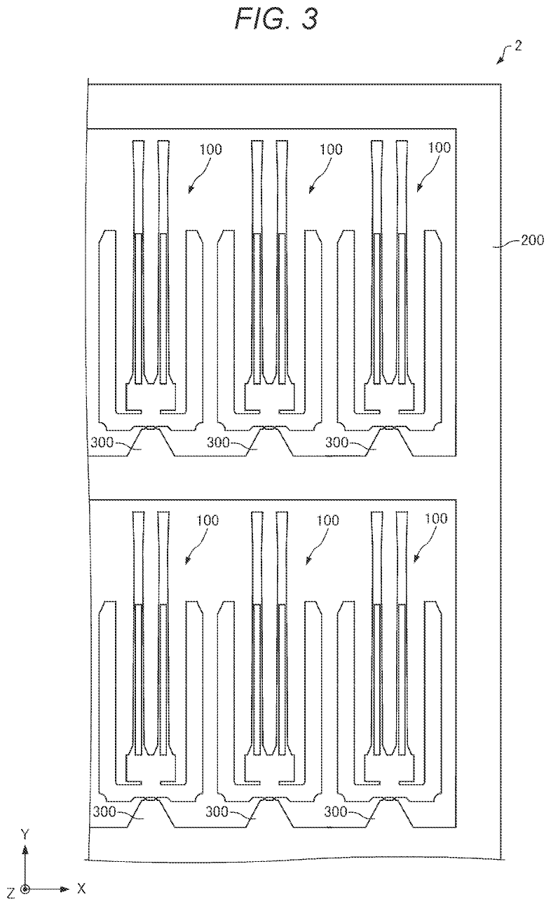

Next, the method of manufacturing the vibration element 100 according to the first embodiment will be described with reference to the drawings. FIG. 2 is a flowchart showing an example of the method of manufacturing the vibration element 100 according to the first embodiment.

The method of manufacturing the vibration element 100 includes a step S10 of manufacturing a piezoelectric substrate 2 including the vibration element 100, a frame portion 200, and a coupling portion 300 by wet etching, and a step S20 of folding the vibration element 100 at the coupling portion 300 and separating the vibration element 100 from the frame portion 200.

### 1.2.2. Piezoelectric Substrate

FIG. 3 is a plan view schematically showing a first surface 2a side of the piezoelectric substrate 2 manufactured in the step S10. FIG. 3 shows an X-axis, a Y-axis, and a Z-axis as three axes orthogonal to one another. Hereinafter, a case in which the piezoelectric substrate 2 is a quartz crystal substrate will be described.

As shown in FIG. 3, a plurality of vibration elements 100 are formed on the piezoelectric substrate 2. Each vibration element 100 is coupled to the frame portion 200 by the coupling portion 300.

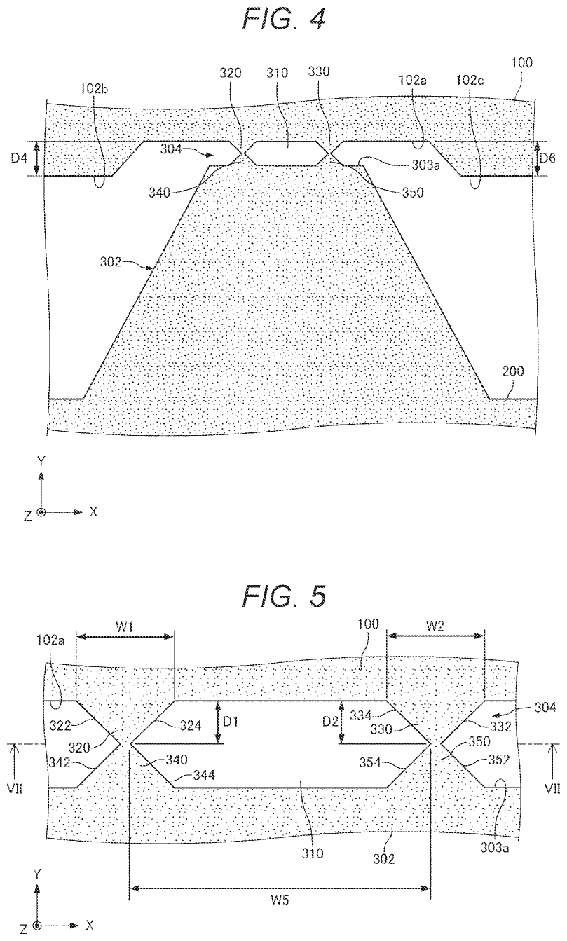

FIG. 4 is a plan view schematically showing the first surface 2a side of the coupling portion 300. As shown in FIG. 4, the coupling portion 300 includes a base end portion 302 and a breaking portion 304. The base end portion 302 is coupled to the frame portion 200. The base end portion 302 protrudes from the frame portion 200 in a +Y direction. The base end portion 302 has, for example, a trapezoidal shape having an upper side 303a when viewed from a direction perpendicular to the first surface 2a, that is, when viewed from a direction along the Z-axis. The upper side 303a of the base end portion 302 and the first side 102a of the vibration element 100 are, for example, parallel to each other.

As shown in FIG. 4, the vibration element 100 has the first side 102a, the second side 102b, and the third side 102c. The first side 102a, the second side 102b, and the third side 102c are outer shape sides that define an outer shape of the vibration element 100. The first side 102a is a side to which the coupling portion 300 is coupled when viewed from the direction perpendicular to the first surface 2a. The second side 102b and the third side 102c sandwich the first side 102a. The second side 102b and the third side 102c are, for example, parallel to the first side 102a. The second side 102b is located at the first support arm 30 side of the first side 102a, and the third side 102c is located at the second support arm 32 side of the first side 102a. In the shown example, the second side 102b is located in a −X direction of the first side 102a, and the third side 102c is located in a +X direction of the first side 102a. The second side 102b and the third side 102c are located in a −Y direction of the first side 102a.

The breaking portion 304 is coupled to the vibration element 100. The breaking portion 304 is located between the vibration element 100 and the base end portion 302. When the vibration element 100 is separated from the frame portion 200, the breaking portion 304 is broken. In a direction along the Y-axis, for example, a size of the breaking portion 304 is smaller than a distance between the first side 102a and the second side 102b and a distance between the first side 102a and the third side 102c.

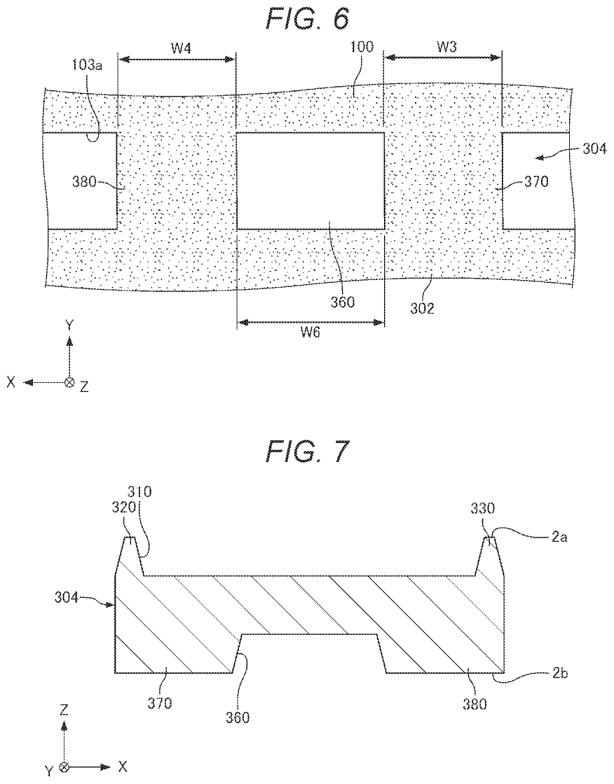

FIGS. 5 and 6 are plan views schematically showing the coupling portion 300. FIG. 5 is a plan view schematically showing the first surface 2a side of the coupling portion 300, and FIG. 6 is a plan view schematically showing a second surface 2b side of the coupling portion 300, the second surface 2b being in a front and rear relationship with the first surface 2a. FIG. 7 is a cross-sectional view schematically showing the coupling portion 300. FIG. 7 is a cross-sectional view taken along a line VII-VII in FIG. 5.

As shown in FIG. 7, the piezoelectric substrate 2 includes the first surface 2a and the second surface 2b. A thickness of the piezoelectric substrate 2, that is, a distance between the first surface 2a and the second surface 2b is, for example, about 130 μm. In the shown example, the thickness of the piezoelectric substrate 2 is a size of the piezoelectric substrate 2 along the Z-axis.

As shown in FIGS. 5 to 7, the breaking portion 304 includes a first groove portion 310, a first protruding portion 320, a second protruding portion 330, a first facing protruding portion 340, a second facing protruding portion 350, a second groove portion 360, a third protruding portion 370, and a fourth protruding portion 380.

As shown in FIG. 5, the breaking portion 304 is formed with the first groove portion 310, the first protruding portion 320, the second protruding portion 330, the first facing protruding portion 340, and the second facing protruding portion 350 at the first surface 2a side. As shown in FIG. 6, the breaking portion 304 is formed with the second groove portion 360, the third protruding portion 370, and the fourth protruding portion 380 at the second surface 2b side.

By forming the first groove portion 310 and the second groove portion 360 in the breaking portion 304, a portion having a small thickness can be formed in the piezoelectric substrate 2. Thereby, the breaking portion 304 can be easily broken in the step S20 of separating the vibration element 100 from the frame portion 200. By forming the breaking portion 304 with the first protruding portion 320, the second protruding portion 330, the first facing protruding portion 340, the second facing protruding portion 350, the third protruding portion 370, and the fourth protruding portion 380, a portion having a large thickness can be formed in the piezoelectric substrate 2. Thereby, a strength of the breaking portion 304 can be improved compared to a case in which no protruding portion is formed in the breaking portion 304. Therefore, it is possible to prevent the vibration element 100 from falling off due to breakage of the coupling portion 300 during conveyance of the piezoelectric substrate 2. As will be described later, by forming the first protruding portion 320, the second protruding portion 330, the first facing protruding portion 340, the second facing protruding portion 350, the third protruding portion 370, and the fourth protruding portion 380 in the breaking portion 304, a breaking position when the vibration element 100 is folded at the coupling portion 300 can be constant.

As shown in FIG. 5, the first groove portion 310 is formed along the first side 102a of the vibration element 100. The first groove portion 310 is sandwiched between the first protruding portion 320 and the second protruding portion 330. In the shown example, the first groove portion 310 is sandwiched between a structure including the first protruding portion 320 and the first facing protruding portion 340 and a structure including the second protruding portion 330 and the second facing protruding portion 350. A depth of the first groove portion 310 is, for example, about 10 μm.

The first protruding portion 320 protrudes from the first side 102a of the vibration element 100. The first protruding portion 320 protrudes along a perpendicular line of the first side 102a when viewed from the direction perpendicular to the first surface 2a. In the shown example, the first protruding portion 320 protrudes in the −Y direction. A tip end of the first protruding portion 320 has the smallest width in the first protruding portion 320. The width of the tip end of the first protruding portion 320 is, for example, about 10 μm.

When viewed from the direction perpendicular to the first surface 2a, the first protruding portion 320 has a first outer shape side 322 that defines an outer shape of the coupling portion 300, and a second outer shape side 324 that defines a boundary between the first groove portion 310 and the first protruding portion 320. The first outer shape side 322 defines an outer shape of the first protruding portion 320 in the −X direction. The second outer shape side 324 defines an outer shape of the first protruding portion 320 in the +X direction. The first outer shape side 322 is inclined with respect to the first side 102a. That is, the first outer shape side 322 is not parallel to the first side 102a and is not perpendicular to the first side 102a. The second outer shape side 324 is inclined with respect to the first side 102a.

A distance between the first outer shape side 322 and the second outer shape side 324 decreases as a distance from the first side 102a increases. That is, a width of the first protruding portion 320 decreases as the distance from the first side 102a increases. The width of the first protruding portion 320 is a size perpendicular to a protruding direction of the first protruding portion 320. In the shown example, the width of the first protruding portion 320 is a size of the first protruding portion 320 along the X-axis.

In the protruding direction of the first protruding portion 320, a distance D1 between the tip end of the first protruding portion 320 and the first side 102a is smaller than a distance D4 between the first side 102a and the second side 102b and a distance D6 between the first side 102a and the third side 102c. The distance D1 is a maximum distance between the tip end of the first protruding portion 320 and the first side 102a in the protruding direction of the first protruding portion 320. The distance D4 is a maximum distance between the first side 102a and the second side 102b in the protruding direction of the first protruding portion 320. The distance D6 is a maximum distance between the first side 102a and the third side 102c in the protruding direction of the first protruding portion 320.

The second protruding portion 330 protrudes from the first side 102a of the vibration element 100. The second protruding portion 330 protrudes along the perpendicular line of the first side 102a when viewed from the direction perpendicular to the first surface 2a. A tip end of the second protruding portion 330 has the smallest width in the second protruding portion 330. The width of the tip end of the second protruding portion 330 is, for example, about 10 μm.

When viewed from the direction perpendicular to the first surface 2a, the second protruding portion 330 has a third outer shape side 332 that defines the outer shape of the coupling portion 300, and a fourth outer shape side 334 that defines a boundary between the first groove portion 310 and the second protruding portion 330. The third outer shape side 332 defines an outer shape of the second protruding portion 330 in the +X direction. The fourth outer shape side 334 defines an outer shape of the second protruding portion 330 in the −X direction. The third outer shape side 332 is inclined with respect to the first side 102a. The fourth outer shape side 334 is inclined with respect to the first side 102a.

A distance between the third outer shape side 332 and the fourth outer shape side 334 decreases as the distance from the first side 102a increases. That is, a width of the second protruding portion 330 decreases as the distance from the first side 102a increases. The width of the second protruding portion 330 is a size perpendicular to a protruding direction of the second protruding portion 330. In the shown example, the width of the second protruding portion 330 is a size of the second protruding portion 330 along the X-axis.

In the protruding direction of the second protruding portion 330, a distance D2 between the tip end of the second protruding portion 330 and the first side 102a is smaller than the distance D4 between the first side 102a and the second side 102b and the distance D6 between the first side 102a and the third side 102c. The distance D2 is a maximum distance between the tip end of the second protruding portion 330 and the first side 102a in the protruding direction of the second protruding portion 330.

The first protruding portion 320 and the second protruding portion 330 have, for example, the same shape and size. The first protruding portion 320 and the second protruding portion 330 may have different shapes and sizes.

The first facing protruding portion 340 protrudes from the upper side 303a of the base end portion 302. The first facing protruding portion 340 protrudes along a perpendicular line of the upper side 303a when viewed from the direction perpendicular to the first surface 2a. In the shown example, the first facing protruding portion 340 protrudes in the +Y direction.

The first facing protruding portion 340 faces the first protruding portion 320. A tip end of the first facing protruding portion 340 is in contact with the tip end of the first protruding portion 320. The first protruding portion 320 and the first facing protruding portion 340 continuously form one structure. For example, when viewed from the direction perpendicular to the first surface 2a, a distance between the first protruding portion 320 and the first side 102a of the vibration element 100 and a distance between the first facing protruding portion 340 and the upper side 303a of the base end portion 302 are equal, and the first protruding portion 320 and the first facing protruding portion 340 are symmetrical with respect to a virtual straight line that is parallel to the X-axis. However, the first protruding portion 320 and the first facing protruding portion 340 may not be symmetrical, and may have different shapes and sizes.

When viewed from the direction perpendicular to the first surface 2a, the first facing protruding portion 340 has a first facing outer shape side 342 that defines the outer shape of the coupling portion 300 and a second facing outer shape side 344 that defines a boundary between the first groove portion 310 and the first facing protruding portion 340. The first facing outer shape side 342 defines an outer shape of the first facing protruding portion 340 in the −X direction. The second facing outer shape side 344 defines an outer shape of the first facing protruding portion 340 in the +X direction. The first facing outer shape side 342 is inclined with respect to the upper side 303a of the base end portion 302. That is, the first facing outer shape side 342 is not parallel to the upper side 303a and is not perpendicular to the upper side 303a. The second facing outer shape side 344 is inclined with respect to the upper side 303a.

A distance between the first facing outer shape side 342 and the second facing outer shape side 344 decreases as a distance from the upper side 303a of the base end portion 302 increases. That is, a width of the first facing protruding portion 340 decreases as the distance from the upper side 303a increases. The width of the first facing protruding portion 340 is a size perpendicular to a protruding direction of the first facing protruding portion 340. In the shown example, the width of the first facing protruding portion 340 is a size of the first facing protruding portion 340 along the X-axis.

The second facing protruding portion 350 protrudes from the upper side 303a of the base end portion 302. The second facing protruding portion 350 protrudes along the perpendicular line of the upper side 303a when viewed from the direction perpendicular to the first surface 2a. In the shown example, the second facing protruding portion 350 protrudes in the +Y direction.

The second facing protruding portion 350 faces the second protruding portion 330. A tip end of the second facing protruding portion 350 is in contact with the tip end of the second protruding portion 330. The second protruding portion 330 and the second facing protruding portion 350 continuously form one structure. For example, when viewed from the direction perpendicular to the first surface 2a, a distance between the second protruding portion 330 and the first side 102a of the vibration element 100 and a distance between the second facing protruding portion 350 and the upper side 303a of the base end portion 302 are equal, and the second protruding portion 330 and the second facing protruding portion 350 are symmetrical with respect to a virtual straight line that is parallel to the X-axis. However, the second protruding portion 330 and the second facing protruding portion 350 may not be symmetrical, and may have different shapes and sizes.

When viewed from the direction perpendicular to the first surface 2a, the second facing protruding portion 350 has a third facing outer shape side 352 that defines the outer shape of the coupling portion 300 and a fourth facing outer shape side 354 that defines a boundary between the first groove portion 310 and the second facing protruding portion 350. The third facing outer shape side 352 defines an outer shape of the second facing protruding portion 350 in the +X direction. The fourth facing outer shape side 354 defines an outer shape of the second facing protruding portion 350 in the −X direction. The third facing outer shape side 352 is inclined with respect to the upper side 303a of the base end portion 302. The fourth facing outer shape side 354 is inclined with respect to the upper side 303a.

A distance between the third facing outer shape side 352 and the fourth facing outer shape side 354 decreases as the distance from the upper side 303a of the base end portion 302 increases. That is, a width of the second facing protruding portion 350 decreases as the distance from the upper side 303a increases. The width of the second facing protruding portion 350 is a size perpendicular to a protruding direction of the second facing protruding portion 350. In the shown example, the width of the second facing protruding portion 350 is a size of the second facing protruding portion 350 along the X-axis.

The first facing protruding portion 340 and the second facing protruding portion 350 have, for example, the same shape and size. However, the first facing protruding portion 340 and the second facing protruding portion 350 may have different shapes and sizes.

As shown in FIG. 6, the second groove portion 360 is provided along a fourth side 103a that defines the outer shape of the vibration element 100. The fourth side 103a is the outer shape side of the vibration element 100 to which the coupling portion 300 is coupled when viewed from a direction perpendicular to the second surface 2b. The second groove portion 360 is sandwiched between the third protruding portion 370 and the fourth protruding portion 380.

The third protruding portion 370 protrudes from the fourth side 103a of the vibration element 100. The third protruding portion 370 protrudes from the vibration element 100 to the base end portion 302. The third protruding portion 370 couples the vibration element 100 and the base end portion 302.

The fourth protruding portion 380 protrudes from the fourth side 103a of the vibration element 100. The fourth protruding portion 380 protrudes from the vibration element 100 to the base end portion 302. The fourth protruding portion 380 couples the vibration element 100 and the base end portion 302.

When a maximum width of the first protruding portion 320 is W1, a maximum width of the second protruding portion 330 is W2, a maximum width of the third protruding portion 370 is W3, a maximum width of the fourth protruding portion 380 is W4, a maximum width of the first groove portion 310 is W5, and a maximum width of the second groove portion 360 is W6, W1+W2<W3+W4, and W5>W6 are satisfied.

Here, the maximum width W1 of the first protruding portion 320 is a maximum size in a direction orthogonal to the protruding direction of the first protruding portion 320. In the shown example, the maximum width W1 of the first protruding portion 320 is the maximum size of the first protruding portion 320 along the X-axis. The first protruding portion 320 has the maximum width W1 at a coupling part between the first protruding portion 320 and the first side 102a. The same applies to the maximum width W2 of the second protruding portion 330.

The maximum width W3 of the third protruding portion 370 is a maximum size in a direction orthogonal to a protruding direction of the third protruding portion 370. In the shown example, the maximum width W3 of the third protruding portion 370 is the maximum size of the third protruding portion 370 along the X-axis. The width of the third protruding portion 370 is, for example, constant. The same applies to the maximum width W4 of the fourth protruding portion 380.

The maximum width W5 of the first groove portion 310 is a maximum size of the first groove portion 310 along the first side 102a. In the shown example, the maximum width W5 of the first groove portion 310 is the maximum size of the first groove portion 310 along the X-axis. The maximum width W6 of the second groove portion 360 is a maximum size of the second groove portion 360 along the fourth side 103a. In the shown example, the maximum width W6 of the second groove portion 360 is the maximum size of the second groove portion 360 along the X-axis.

A surface of the first protruding portion 320 facing a +Z direction, a surface of the second protruding portion 330 facing the +Z direction, a surface of the first facing protruding portion 340 facing the +Z direction, and a surface of the second facing protruding portion 350 facing the +Z direction form, for example, the first surface 2a of the piezoelectric substrate 2. The surfaces facing the +Z direction are, for example, flush with a surface of the base portion 10 of the vibration element 100 facing the +Z direction and a surface of the base end portion 302 facing the +Z direction. A surface of the third protruding portion 370 facing a −Z direction and a surface of the fourth protruding portion 380 facing the −Z direction form, for example, the second surface 2b of the piezoelectric substrate 2. The surfaces facing the −Z direction are, for example, flush with a surface of the base portion 10 of the vibration element 100 facing the −Z direction and a surface of the base end portion 302 of the coupling portion 300 facing the −Z direction.

### 1.2.3. Step S10 of Manufacturing Piezoelectric Substrate Including Vibration Element, Frame Portion, and Coupling Portion

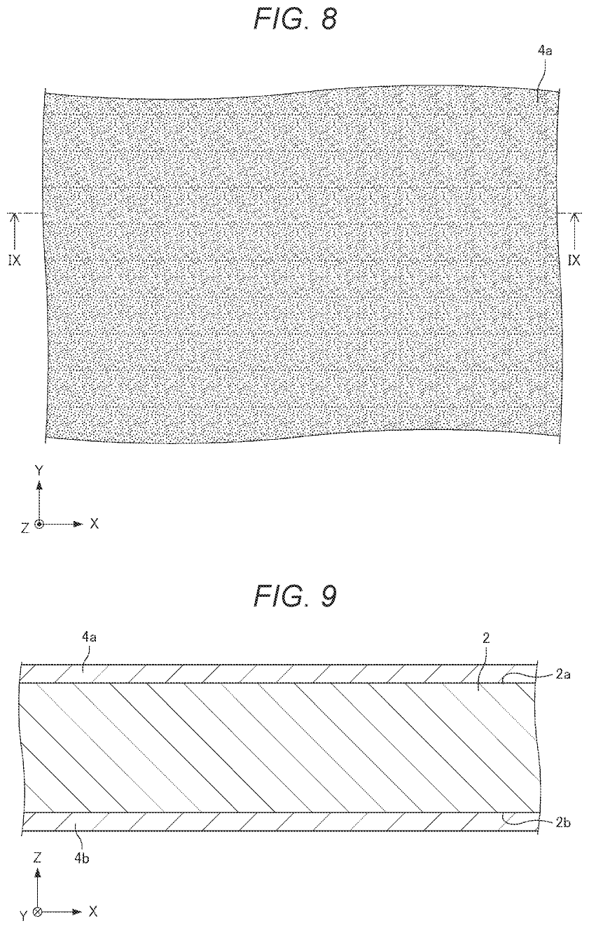

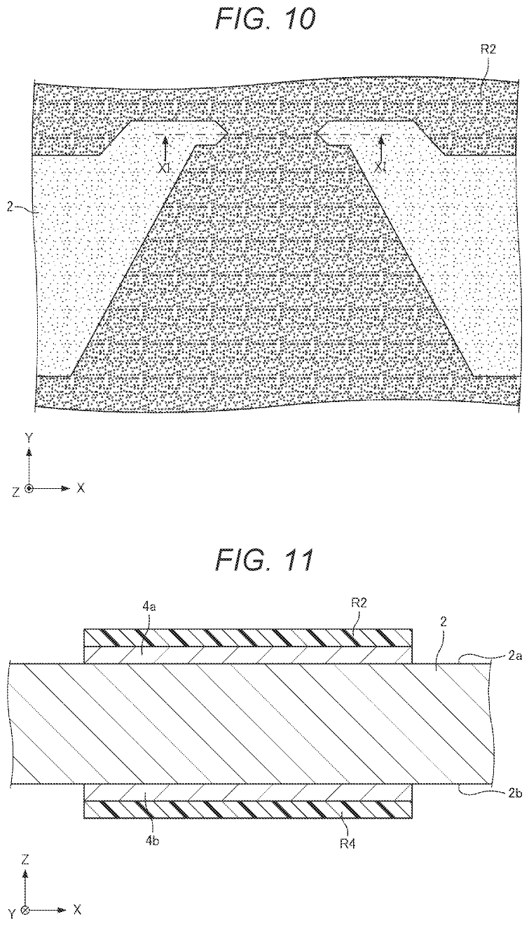

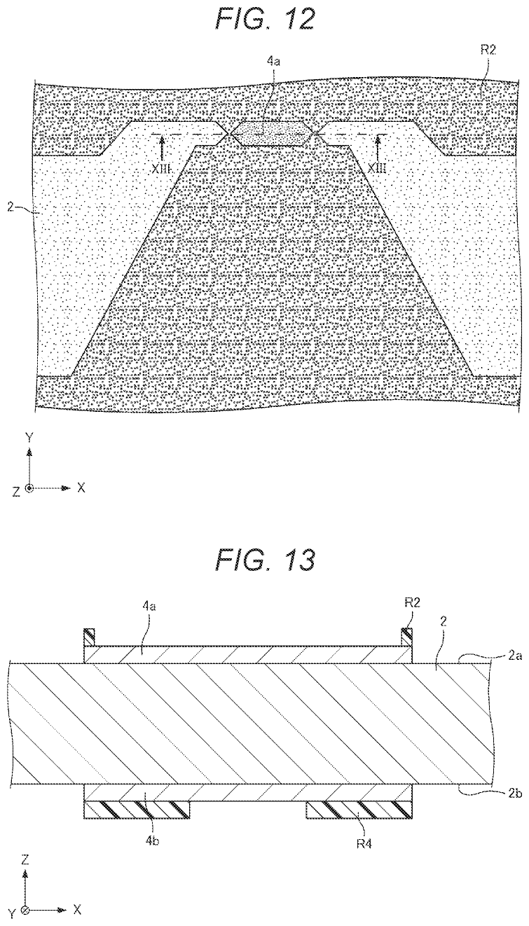

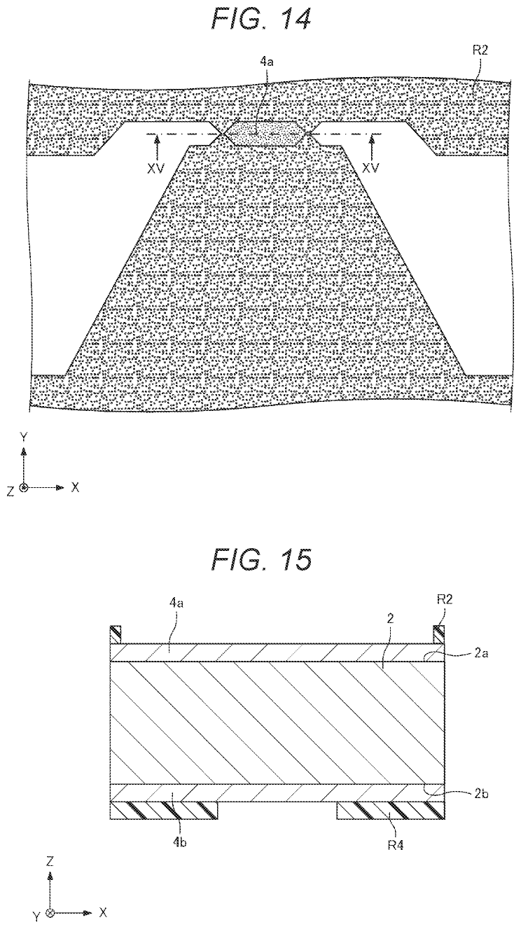

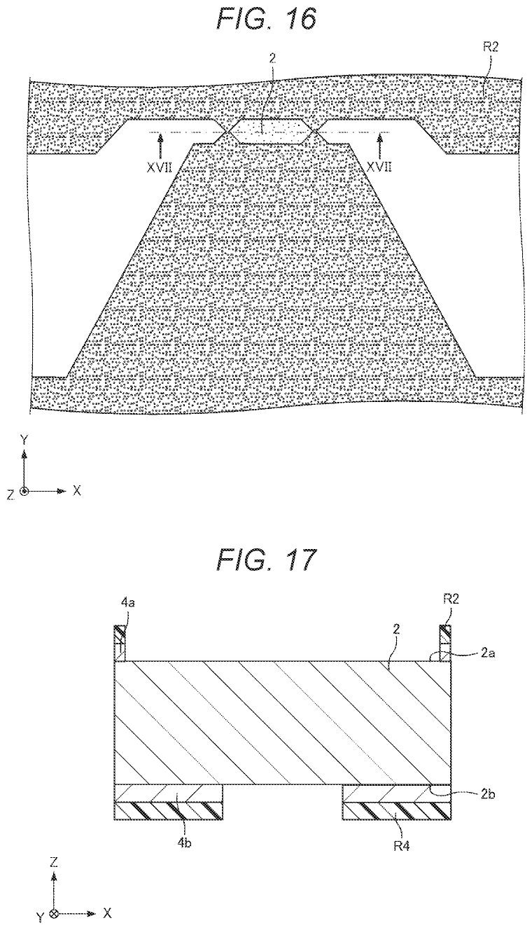

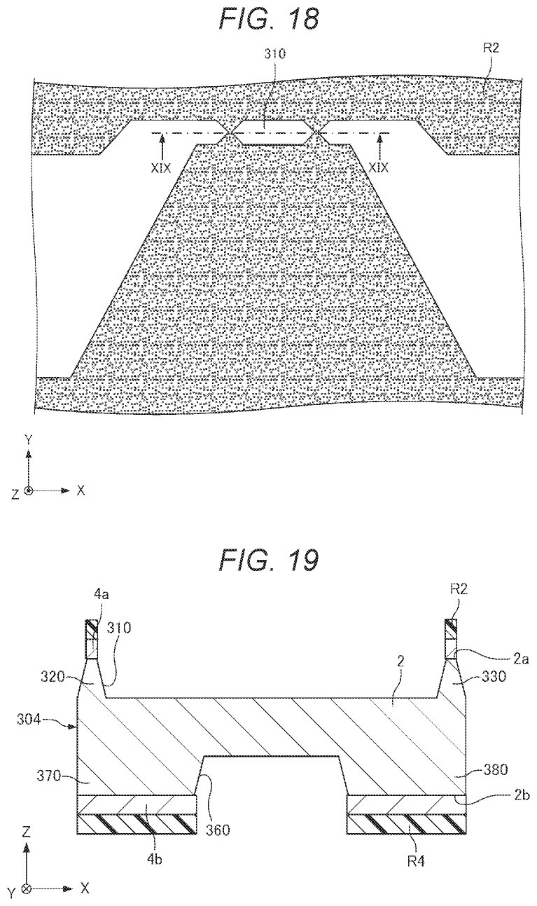

FIGS. 8 to 19 are diagrams schematically showing a process of manufacturing the vibration element 100. FIG. 8, FIG. 10, FIG. 12, FIG. 14, FIG. 16, and FIG. 18 are plan views schematically showing the process of manufacturing the vibration element 100 and correspond to FIG. 4. FIG. 9 is a cross-sectional view taken along a line IX-IX in FIG. 8. FIG. 11 is a cross-sectional view taken along a line XI-XI in FIG. 10. FIG. 13 is a cross-sectional view taken along a line XIII-XIII in FIG. 12. FIG. 15 is a cross-sectional view taken along a line XV-XV in FIG. 14. FIG. 17 is a cross-sectional view taken along a line XVII-XVII in FIG. 16. FIG. 19 is a cross-sectional view taken along a line XIX-XIX in FIG. 18.

First, as shown in FIGS. 8 and 9, a first corrosion-resistant film 4a is formed at the first surface 2a of the piezoelectric substrate 2, and a second corrosion-resistant film 4b is formed at the second surface 2b. Hereinafter, a case in which the piezoelectric substrate 2 is a quartz crystal substrate will be described.

The first corrosion-resistant film 4a and the second corrosion-resistant film 4b are, for example, laminated films in which chromium and gold are laminated in this order. The first corrosion-resistant film 4a and the second corrosion-resistant film 4b can be formed by, for example, a vacuum deposition method, a sputtering method, or the like.

Next, as shown in FIGS. 10 and 11, a resist R2 is formed on the first corrosion-resistant film 4a, and a resist R4 is formed on the second corrosion-resistant film 4b. Next, the resist R2 and the resist R4 are patterned. The resist R2 is patterned into shapes of the outer shapes of the vibration element 100, the frame portion 200, and the coupling portion 300 at the first surface 2a side, and the resist R4 is patterned into shapes of the outer shapes of the vibration element 100, the frame portion 200, and the coupling portion 300 at the second surface 2b side. The resist R2 and the resist R4 are photosensitive resins and can be patterned by exposure and development.

Next, the first corrosion-resistant film 4a is patterned using the resist R2 as a mask, and the second corrosion-resistant film 4b is patterned using the resist R4 as a mask. By patterning the first corrosion-resistant film 4a using the resist R2 as a mask, the first corrosion-resistant film 4a is patterned into the shapes of the outer shapes of the vibration element 100, the frame portion 200, and the coupling portion 300 at the first surface 2a side. That is, sides corresponding to the first side 102a, the second side 102b, and the third side 102c, which are the outer shape sides of the vibration element 100, are formed at the first corrosion-resistant film 4a. Further, sides corresponding to the first outer shape side 322, the third outer shape side 332, the first facing outer shape side 342, the third facing outer shape side 352, and the upper side 303a, which are the outer shape sides of the coupling portion 300, are formed at the first corrosion-resistant film 4a. By patterning the second corrosion-resistant film 4b using the resist R4 as a mask, the second corrosion-resistant film 4b is patterned into the shapes of the outer shapes of the vibration element 100, the frame portion 200, and the coupling portion 300 on the second surface 2b side.

Next, as shown in FIGS. 12 and 13, a region corresponding to the first groove portion 310 is removed from the resist R2. At this time, although not shown, a region corresponding to the long groove 21 of the first vibration arm 20 at the first surface 2a side and a region corresponding to the long groove 23 of the second vibration arm 22 at the first surface 2a side are removed from the resist R2. A region corresponding to the second groove portion 360 is removed from the resist R4. At this time, although not shown, a region corresponding to the long groove 21 of the first vibration arm 20 at the second surface 2b side and a region corresponding to the long groove 23 of the second vibration arm 22 at the second surface 2b side are removed from the resist R4. In the resist R2 and the resist R4, a desired region can be removed by exposure and development.

Next, as shown in FIGS. 14 and 15, the piezoelectric substrate 2 is etched using the first corrosion-resistant film 4a and the second corrosion-resistant film 4b as masks. Etching of the piezoelectric substrate 2 is performed by, for example, wet etching using hydrofluoric acid or the like as an etchant. Thereby, the outer shapes of the vibration element 100, the frame portion 200, and the coupling portion 300 are formed. That is, the first outer shape side 322, the third outer shape side 332, the first facing outer shape side 342, the third facing outer shape side 352, and the upper side 303a are formed at the first surface 2a of the piezoelectric substrate 2.

Next, as shown in FIGS. 16 and 17, the first corrosion-resistant film 4a is etched using the resist R2 as a mask, and the second corrosion-resistant film 4b is etched using the resist R4 as a mask. Thereby, a region corresponding to the first groove portion 310 can be removed from the first corrosion-resistant film 4a. Accordingly, sides corresponding to the second outer shape side 324, the fourth outer shape side 334, the second facing outer shape side 344, and the fourth facing outer shape side 354 that define the boundaries of the first groove portion 310 are formed at the first corrosion-resistant film 4a. Further, although not shown, the region corresponding to the long groove 21 of the first vibration arm 20 at the first surface 2a side and the region corresponding to the long groove 23 of the second vibration arm 22 at the first surface 2a side can be removed from the first corrosion-resistant film 4a. Further, a region corresponding to the second groove portion 360 can be removed from the second corrosion-resistant film 4b. Further, although not shown, the region corresponding to the long groove 21 of the first vibration arm 20 at the second surface 2b side and the region corresponding to the long groove 23 of the second vibration arm 22 at the second surface 2b side can be removed from the second corrosion-resistant film 4b.

Next, as shown in FIGS. 18 and 19, the piezoelectric substrate 2 is half-etched using the first corrosion-resistant film 4a and the second corrosion-resistant film 4b as masks. Thereby, the first groove portion 310, the first protruding portion 320, the second protruding portion 330, the first facing protruding portion 340, and the second facing protruding portion 350 are formed on the piezoelectric substrate 2 at the first surface 2a side. Further, the long groove 21 is formed in the first vibration arm 20 at the first surface 2a side, and the long groove 23 is formed in the second vibration arm 22 at the first surface 2a side. The second groove portion 360, the third protruding portion 370, and the fourth protruding portion 380 are formed on the piezoelectric substrate 2 at the second surface 2b side. Further, the long groove 21 is formed in the first vibration arm 20 at the second surface 2b side, and the long groove 23 is formed in the second vibration arm 22 at the second surface 2b side.

Next, as shown in FIG. 4, the resist R2, the resist R4, the first corrosion-resistant film 4a, and the second corrosion-resistant film 4b are removed. Next, although not shown, drive electrodes are formed on the first vibration arm 20 and the second vibration arm 22.

Through the above steps, it is possible to manufacture the piezoelectric substrate 2 in which a plurality of vibration elements 100 coupled to the frame portion 200 by the coupling portion 300 shown in FIGS. 3 to 7 are formed.

1.2.4. Step S20 of Separating Vibration Element from Frame Portion

FIG. 20 is a diagram showing a step of separating the vibration element 100 from the frame portion 200.

As shown in FIG. 20, the vibration element 100 coupled to the frame portion 200 via the coupling portion 300 is folded at the coupling portion 300 and separated from the frame portion 200. Specifically, first, the frame portion 200 is sandwiched and fixed by a clamp 400. Next, a suction nozzle 500 is pushed toward the first surface 2a side of the vibration element 100. Thereby, the coupling portion 300 is broken at the breaking portion 304, and the vibration element 100 can be separated from the frame portion 200. Next, the vibration element 100 separated from the frame portion 200 is sucked and conveyed by the suction nozzle 500.

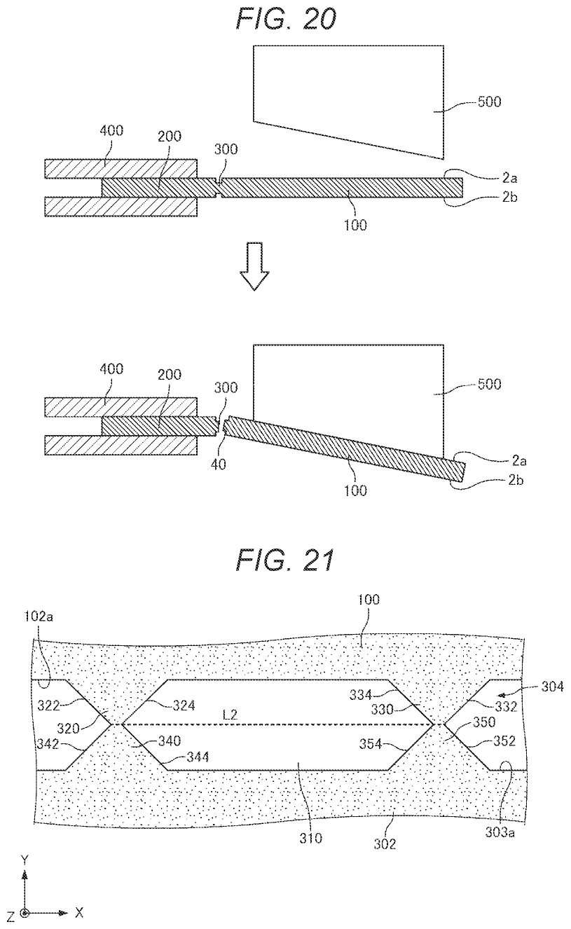

FIG. 21 is a plan view schematically showing the first surface 2a side of the coupling portion 300. In FIG. 21, a broken line indicates a position where the breaking portion 304 breaks.

As shown in FIG. 21, when the suction nozzle 500 is pushed toward the first surface 2a side of the vibration element 100, the breaking portion 304 breaks at a position indicated by a virtual straight line L2 coupling the tip end of the first protruding portion 320 and the tip end of the second protruding portion 330 when viewed from the direction perpendicular to the first surface 2a. The reason will be described below.

The first protruding portion 320 is formed such that the distance between the first outer shape side 322 and the second outer shape side 324 decreases as the distance from the first side 102a of the vibration element 100 increases. The second protruding portion 330 is formed such that the distance between the third outer shape side 332 and the fourth outer shape side 334 decreases as the distance from the first side 102a of the vibration element 100 increases. The first facing protruding portion 340 is formed such that the distance between the first facing outer shape side 342 and the second facing outer shape side 344 decreases as the distance from the upper side 303a of the base end portion 302 increases. The tip end of the first facing protruding portion 340 is in contact with the tip end of the first protruding portion 320. The second facing protruding portion 350 is formed such that the distance between the third facing outer shape side 352 and the fourth facing outer shape side 354 decreases as the distance from the upper side 303a of the base end portion 302 increases. The tip end of the second facing protruding portion 350 is in contact with the tip end of the second protruding portion 330. As described above, the width of the first protruding portion 320 is smallest at the tip end. The width of the second protruding portion 330 is smallest at the tip end. Therefore, when the vibration element 100 is folded at the coupling portion 300, stress concentrates on the tip end of the first protruding portion 320 and the tip end of the second protruding portion 330.

Accordingly, when the suction nozzle 500 is pushed toward the first surface 2a side of the vibration element 100, stress concentrates on the tip end of the first protruding portion 320 and the tip end of the second protruding portion 330, and the breaking portion 304 breaks with the tip end of the first protruding portion 320 and the tip end of the second protruding portion 330 as starting points. As a result, the breaking portion 304 breaks at the position indicated by the virtual straight line L2 coupling the tip end of the first protruding portion 320 and the tip end of the second protruding portion 330.

The maximum width W1 of the first protruding portion 320, the maximum width W2 of the second protruding portion 330, the maximum width W3 of the third protruding portion 370, the maximum width W4 of the fourth protruding portion 380, the maximum width W5 of the first groove portion 310, and the maximum width W6 of the second groove portion 360 satisfy W1+W2<W3+W4, and W5>W6. Therefore, a strength of the coupling portion 300 at the first surface 2a side can be made smaller than a strength of the coupling portion 300 at the second surface 2b side. Accordingly, as shown in FIG. 20, when the suction nozzle 500 is pushed toward the first surface 2a side of the vibration element 100, the coupling portion 300 can be broken from the first surface 2a side.

In the protruding direction of the first protruding portion 320, the distance D1 between the tip end of the first protruding portion 320 and the first side 102a is smaller than the distance D4 between the first side 102a and the second side 102b and the distance D6 between the first side 102a and the third side 102c. Further, in the protruding direction of the second protruding portion 330, the distance D2 between the tip end of the second protruding portion 330 and the first side 102a is smaller than the distance D4 between the first side 102a and the second side 102b and the distance D6 between the first side 102a and the third side 102c. Accordingly, a length by which the folding trace 40, which is the remaining portion of the coupling portion 300 shown in FIG. 1, protrudes from the second side 102b and the third side 102c can be reduced, or the folding trace 40 can be prevented from protruding from the second side 102b and the third side 102c. Accordingly, for example, as shown in FIG. 1, the folding trace 40 can be disposed inside the recessed portion 101. As described above, since the coupling portion 300 breaks at the position indicated by the virtual straight line L2 coupling the tip end of the first protruding portion 320 and the tip end of the second protruding portion 330, the folding trace 40 includes at least a part of the first protruding portion 320 and the second protruding portion 330.

### 1.3. Operation and Effect

The method of manufacturing the vibration element 100 according to the first embodiment includes the step S10 of manufacturing the piezoelectric substrate 2 including the vibration element 100, the frame portion 200, and the coupling portion 300, and the step S20 of folding the vibration element 100 at the coupling portion 300 and separating the vibration element 100 from the frame portion 200. In the step S10, the coupling portion 300 is formed with the first groove portion 310, the first protruding portion 320, and the second protruding portion 330 on the first surface 2a. Further, in the step S10, the first protruding portion 320 is formed in a shape in which the distance between the first outer shape side 322 and the second outer shape side 324 decreases as the distance from the first side 102a of the vibration element 100 increases. Further, in the step S10, the first outer shape side 322 and the second outer shape side 324 are formed to be inclined with respect to the first side 102a of the vibration element 100. Further, in the step S10, the second protruding portion 330 is formed in a shape in which the distance between the third outer shape side 332 and the fourth outer shape side 334 decreases as the distance from the first side 102a of the vibration element 100 increases when viewed from the direction perpendicular to the first surface 2a. Further, in the step S10, the third outer shape side 332 and the fourth outer shape side 334 are formed to be inclined with respect to the first side 102a of the vibration element 100.

As described above, in the method of manufacturing the vibration element 100 according to the first embodiment, the coupling portion 300 is formed with the first protruding portion 320 and the second protruding portion 330. Therefore, when the vibration element 100 is folded at the coupling portion 300 in the step S20, stress concentrates on the tip end of the first protruding portion 320 and the tip end of the second protruding portion 330, and the coupling portion 300 breaks with the tip end of the first protruding portion 320 and the tip end of the second protruding portion 330 as starting points. Accordingly, in the method of manufacturing the vibration element 100 according to the first embodiment, a breaking position when the vibration element 100 is folded at the coupling portion 300 can be constant. As a result, the folding trace 40 remaining after the vibration element 100 is folded from the frame portion 200 can be made small.

In the method of manufacturing the vibration element 100 according to the first embodiment, in the step S10, the second side 102b and the third side 102c located in the protruding direction of the first protruding portion 320 with respect to the first side 102a are formed on the vibration element 100 when viewed from the direction perpendicular to the first surface 2a. Further, in the step S10, in the protruding direction of the first protruding portion 320, the distance D1 between the tip end of the first protruding portion 320 and the first side 102a is smaller than the distance D4 between the first side 102a and the second side 102b and the distance D6 between the first side 102a and the third side 102c. Further, in the step S10, in the protruding direction of the second protruding portion 330, the distance D2 between the tip end of the second protruding portion 330 and the first side 102a is formed to be smaller than the distance D4 and the distance D6.

Therefore, in the step S20, the length by which the folding trace 40 protrudes from the second side 102b and the third side 102c can be reduced, or the folding trace 40 can be prevented from protruding from the second side 102b and the third side 102c.

For example, when the folding trace 40 of the vibration element 100 is large, the folding trace 40 may interfere with the package in mounting the vibration element 100 on the package. In particular, when the vibration element 100 and the package are downsized, a proportion of the folding trace 40 to the entire vibration element 100 is relatively large, which causes a problem. In the method of manufacturing the vibration element 100 according to the first embodiment, as described above, since the folding trace 40 can be made small, the vibration element 100 and the package can be downsized.

In the method of manufacturing the vibration element 100 according to the first embodiment, the maximum width W1 of the first protruding portion 320, the maximum width W2 of the second protruding portion 330, the maximum width W3 of the third protruding portion 370, the maximum width W4 of the fourth protruding portion 380, the maximum width W5 of the first groove portion 310, and the maximum width W6 of the second groove portion 360 satisfy W1+W2<W3+W4, and W5>W6. Therefore, in the method of manufacturing the vibration element 100 according to the first embodiment, the strength of the coupling portion 300 at the first surface 2a side can be made smaller than the strength of the coupling portion 300 at the second surface 2b side. Therefore, when the vibration element 100 is folded at the coupling portion 300 in the step S20, the coupling portion 300 can be easily broken from the first surface 2a side. Accordingly, in the method of manufacturing the vibration element 100 according to the first embodiment, a breaking position when the vibration element 100 is folded at the coupling portion 300 can be constant.

### 2. Second Embodiment

### 2.1. Method of Manufacturing Vibration Element

### 2.2.1. Flow of Method of Manufacturing Vibration Element

Next, a method of manufacturing the vibration element 100 according to a second embodiment will be described with reference to the drawings. Similar to the method of manufacturing the vibration element 100 according to the first embodiment, the method of manufacturing the vibration element 100 according to the second embodiment includes the step S10 of manufacturing the piezoelectric substrate 2 including the vibration element 100, the frame portion 200, and the coupling portion 300, and the step S20 of separating the vibration element 100 from the frame portion 200.

Hereinafter, points different from the example of the method of manufacturing the vibration element 100 according to the first embodiment described above will be described, and description of similar points will be omitted.

### 2.2.2. Piezoelectric Substrate

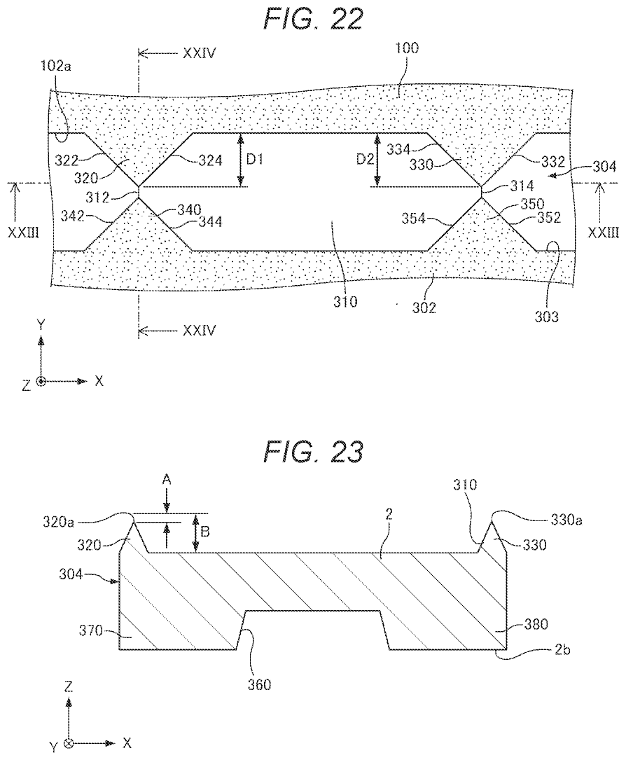

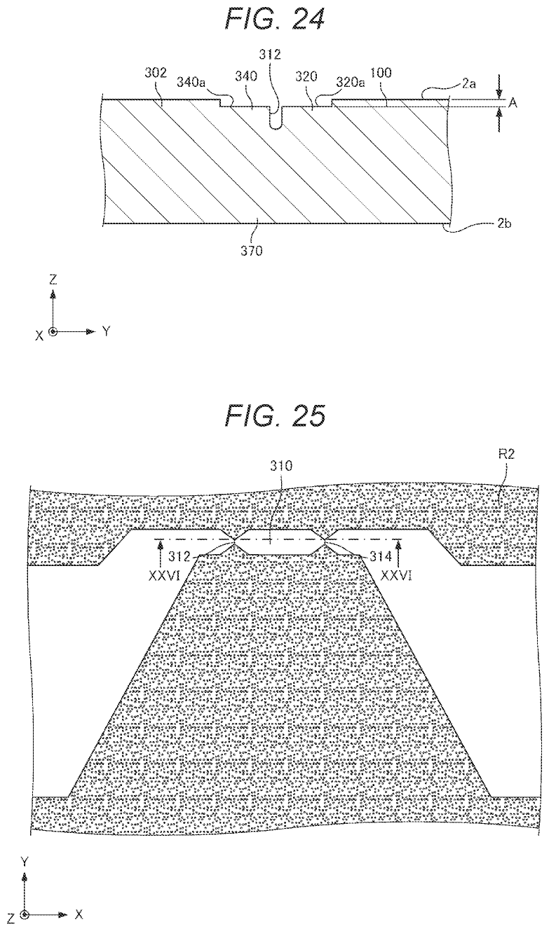

FIG. 22 is a plan view schematically showing the coupling portion 300. FIGS. 23 and 24 are cross-sectional views schematically showing the coupling portion 300. FIG. 23 is a cross-sectional view taken along a line XXIII-XXIII in FIG. 22. FIG. 24 is a cross-sectional view taken along a line XXIV-XXIV in FIG. 22. Hereinafter, in the piezoelectric substrate 2 according to the second embodiment, members having the same functions as constituent members of the piezoelectric substrate 2 according to the first embodiment described above are denoted by the same reference numerals, and detailed description thereof is omitted.

In the method of manufacturing the vibration element 100 according to the first embodiment, as shown in FIG. 5, the tip end of the first protruding portion 320 and the tip end of the first facing protruding portion 340 are in contact with each other, and the tip end of the second protruding portion 330 and the tip end of the second facing protruding portion 350 are in contact with each other.

On the other hand, in the method of manufacturing the vibration element 100 according to the second embodiment, as shown in FIGS. 22 to 24, the tip end of the first protruding portion 320 and the tip end of the first facing protruding portion 340 are not in contact with each other, and the tip end of the second protruding portion 330 and the tip end of the second facing protruding portion 350 are not in contact with each other. A first recessed portion 312 continuous with the first groove portion 310 is formed between the tip end of the first protruding portion 320 and the tip end of the first facing protruding portion 340. A second recessed portion 314 continuous with the first groove portion 310 is formed between the tip end of the second protruding portion 330 and the tip end of the second facing protruding portion 350.

As shown in FIG. 22, the first protruding portion 320 is formed such that the first outer shape side 322 and the second outer shape side 324 intersect with each other at the tip end of the first protruding portion 320. An intersection of the first outer shape side 322 and the second outer shape side 324 forms the tip end of the first protruding portion 320. That is, the first protruding portion 320 is formed in a V shape. The second protruding portion 330 is formed such that the third outer shape side 332 and the fourth outer shape side 334 intersect with each other at the tip end of the second protruding portion 330. An intersection of the third outer shape side 332 and the fourth outer shape side 334 forms the tip end of the second protruding portion 330. That is, the second protruding portion 330 is formed in a V shape.

The first facing protruding portion 340 is formed such that the first facing outer shape side 342 and the second facing outer shape side 344 intersect with each other at the tip end of the first facing protruding portion 340. A virtual straight line coupling the tip end of the first facing protruding portion 340 and the tip end of the first protruding portion 320 is, for example, parallel to the Y-axis.

The second facing protruding portion 350 is formed such that the third facing outer shape side 352 and the fourth facing outer shape side 354 intersect with each other at the tip end of the second facing protruding portion 350. A virtual straight line coupling the tip end of the second facing protruding portion 350 and the tip end of the second protruding portion 330 is, for example, parallel to the Y-axis.

As shown in FIGS. 23 and 24, an upper surface 320a of the first protruding portion 320 is located in the −Z direction of the first surface 2a. A depth A of the upper surface 320a of the first protruding portion 320 is, for example, smaller than half a depth B of the first groove portion 310. That is, A<(B/2) is satisfied. The depth A of the upper surface 320a of the first protruding portion 320 is a distance between the first surface 2a and the upper surface 320a in the direction along the Z-axis. The depth A is a maximum depth of the upper surface 320a with respect to the first surface 2a. The depth B of the first groove portion 310 is a distance between the first surface 2a and a bottom surface of the first groove portion 310 in the direction along the Z-axis. The depth B is a maximum depth of the first groove portion 310 with respect to the first surface 2a.

When A<(B/2) is satisfied, a difference in thickness of the piezoelectric substrate 2 between the first protruding portion 320 and the first groove portion 310 can be increased. Accordingly, when the vibration element 100 is folded at the coupling portion 300, stress can be concentrated on the tip end of the first protruding portion 320 as compared with, for example, a case in which A<(B/2) is not satisfied.

In the example shown in FIG. 24, the depth A of the upper surface 320a of the first protruding portion 320 is constant. Although not shown, the depth A of the upper surface 320a of the first protruding portion 320 may increase from the first side 102a of the vibration element 100 toward the first recessed portion 312. That is, for the first protruding portion 320, the depth A may increase toward the tip end of the first protruding portion 320. In this case, the upper surface 320a of the first protruding portion 320 is inclined with respect to an XY plane.

Although not shown, an upper surface 330a of the second protruding portion 330, an upper surface 340a of the first facing protruding portion 340, and an upper surface of the second facing protruding portion 350 are also located in the −Z direction of the first surface 2a, similar to the upper surface 320a of the first protruding portion 320. The depth A of the upper surface 320a of the first protruding portion 320, a depth of the upper surface 330a of the second protruding portion 330, a depth of the upper surface 340a of the first facing protruding portion 340, and a depth of the upper surface of the second facing protruding portion 350 are, for example, equal to each other. However, the depth A of the upper surface 320a of the first protruding portion 320, the depth of the upper surface 330a of the second protruding portion 330, the depth of the upper surface 340a of the first facing protruding portion 340, and the depth of the upper surface of the second facing protruding portion 350 may be different from each other.

The first recessed portion 312 is formed between the tip end of the first protruding portion 320 and the tip end of the first facing protruding portion 340. The first recessed portion 312 is formed between the first protruding portion 320 and the frame portion 200. The second recessed portion 314 is formed between the tip end of the second protruding portion 330 and the tip end of the second facing protruding portion 350. The second recessed portion 314 is formed between the second protruding portion 330 and the frame portion 200. The first recessed portion 312, the first groove portion 310, and the second recessed portion 314 form one continuous groove. The groove formed by the first recessed portion 312, the first groove portion 310, and the second recessed portion 314 is formed from the end in a −X-axis direction to the end in a +X-axis direction of the breaking portion 304.

A depth of the first recessed portion 312 and a depth of the second recessed portion 314 are, for example, equal to or less than the depth of the first groove portion 310. The depth of the first recessed portion 312 and the depth of the second recessed portion 314 may be the same as or different from each other.

The second groove portion 360, the third protruding portion 370, and the fourth protruding portion 380 formed at the second surface 2b side are the same as those of the vibration element 100 according to the first embodiment shown in FIG. 6, and the description thereof is omitted.

### 2.2.3. Step S10 of Manufacturing Piezoelectric Substrate Including Vibration Element, Frame Portion, and Coupling Portion

FIGS. 25 and 26 are diagrams schematically showing a process of manufacturing the vibration element 100. FIG. 25 is a plan view schematically showing the process of manufacturing the vibration element 100. FIG. 26 is a cross-sectional view taken along a line XXVI-XXVI in FIG. 25.

A step of forming the first corrosion-resistant film 4a and the second corrosion-resistant film 4b shown in FIGS. 8 and 9, a step of forming the resist R2 and the resist R4 shown in FIGS. 10 to 13, a step of etching the piezoelectric substrate 2 shown in FIGS. 14 and 15, and a step of etching the first corrosion-resistant film 4a and the second corrosion-resistant film 4b shown in FIGS. 16 and 17 are the same as those in the method of manufacturing the vibration element 100 according to the first embodiment described above, and the description thereof is omitted.

After the step of etching the first corrosion-resistant film 4a and the second corrosion-resistant film 4b shown in FIGS. 16 and 17, as shown in FIGS. 25 and 26, the piezoelectric substrate 2 is etched using the first corrosion-resistant film 4a and the second corrosion-resistant film 4b as masks. Thereby, the first groove portion 310, the first recessed portion 312, the second recessed portion 314, the first protruding portion 320, the second protruding portion 330, the first facing protruding portion 340, and the second facing protruding portion 350 are formed on the piezoelectric substrate 2 at the first surface 2a side. The second groove portion 360, the third protruding portion 370, and the fourth protruding portion 380 are formed on the piezoelectric substrate 2 at the second surface 2b side.

At this time, the first protruding portion 320 is side-etched. That is, the piezoelectric substrate 2 is etched not only in the direction along the Z-axis but also in the direction along the X-axis. For example, the first protruding portion 320 may be side-etched by reducing a width of a mask for forming the first protruding portion 320. For example, the piezoelectric substrate 2 may be etched under conditions in which side-etching proceeds. In this step, for example, the first protruding portion 320 is side-etched such that the depth A of the upper surface 320a of the first protruding portion 320 is half or less of the depth B of the first groove portion 310. The second protruding portion 330, the first facing protruding portion 340, and the second facing protruding portion 350 are also side-etched similar to the first protruding portion 320.

Next, the resist R2, the resist R4, the first corrosion-resistant film 4a, and the second corrosion-resistant film 4b are removed. Next, although not shown, drive electrodes are formed on the first vibration arm 20 and the second vibration arm 22.

Through the above steps, it is possible to manufacture the piezoelectric substrate 2 in which a plurality of vibration elements 100 coupled to the frame portion 200 by the coupling portion 300 shown in FIGS. 22 to 24 are formed.

2.2.4. Step S20 of Separating Vibration Element from Frame Portion

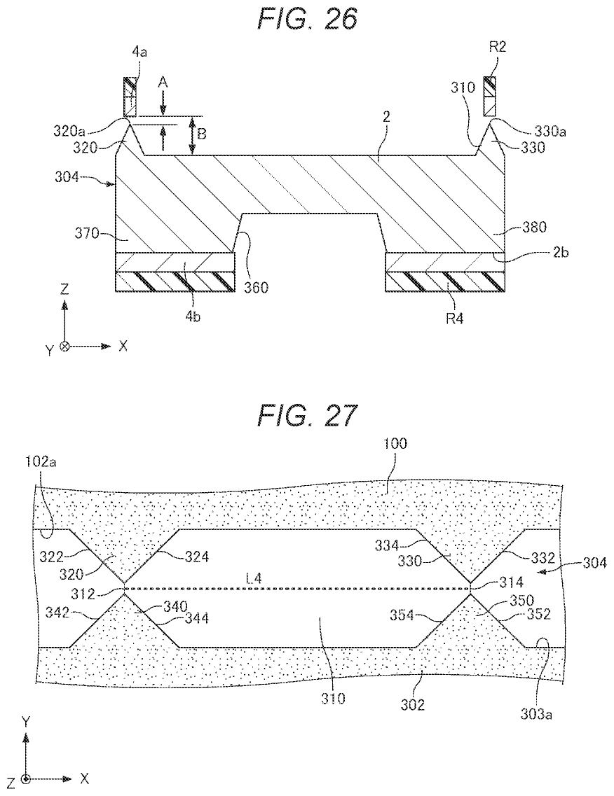

FIG. 27 is a plan view schematically showing the coupling portion 300. In FIG. 27, a broken line indicates a position where the breaking portion 304 breaks.

When the suction nozzle 500 is pushed toward the first surface 2a side of the vibration element 100, as shown in FIG. 27, the breaking portion 304 breaks at a position indicated by a virtual straight line L4 coupling a center of the first recessed portion 312 and a center of the second recessed portion 314 when viewed from the direction perpendicular to the first surface 2a.

When the vibration element 100 is folded at the coupling portion 300, stress concentrates on the tip end of the first protruding portion 320, the tip end of the second protruding portion 330, the tip end of the first facing protruding portion 340, and the tip end of the second facing protruding portion 350. The thickness of the piezoelectric substrate 2 decreases and the strength decreases at a position where the first recessed portion 312 is formed and a position where the second recessed portion 314 is formed. Therefore, when the vibration element 100 is folded at the coupling portion 300, a position which is adjacent to the tip end of the first protruding portion 320 and the tip end of the first facing protruding portion 340 and where the first recessed portion 312 is formed serves as a starting point of breakage. Similarly, a position which is adjacent to the tip end of the second protruding portion 330 and the tip end of the second facing protruding portion 350 and where the second recessed portion 314 is formed serves as a starting point of breakage. As a result, the breaking portion 304 breaks at the position indicated by the virtual straight line L4. Accordingly, in the method of manufacturing the vibration element 100 according to the second embodiment, a breaking position when the vibration element 100 is folded at the coupling portion 300 can be constant.

### 2.3. Operation and Effect

The method of manufacturing the vibration element 100 according to the second embodiment can achieve the same effects as those of the method of manufacturing the vibration element 100 according to the first embodiment.

Further, in the method of manufacturing the vibration element 100 according to the second embodiment, in the step S10, the first outer shape side 322 and the second outer shape side 324 are formed to intersect with each other at the tip end of the first protruding portion 320. Further, in the step S10, the third outer shape side 332 and the fourth outer shape side 334 are formed to intersect with each other at the tip end of the second protruding portion 330. Further, in the step S10, the first recessed portion 312 continuous with the first groove portion 310 is formed between the first protruding portion 320 and the frame portion 200, and the second recessed portion 314 continuous with the first groove portion 310 is formed between the second protruding portion 330 and the frame portion 200.

Therefore, when the vibration element 100 is folded at the coupling portion 300 in the step S20, stress concentrates on the tip end of the first protruding portion 320 and the tip end of the second protruding portion 330. Accordingly, in the method of manufacturing the vibration element 100 according to the second embodiment, a breaking position when the vibration element 100 is folded at the coupling portion 300 can be constant. As a result, the folding trace 40 can be made small.

### 3. Third Embodiment

### 3.1. Method of Manufacturing Vibration Element

### 3.2.1. Flow of Method of Manufacturing Vibration Element

Next, a method of manufacturing the vibration element 100 according to a third embodiment will be described with reference to the drawings. Similar to the method of manufacturing the vibration element 100 according to the first embodiment, the method of manufacturing the vibration element 100 according to the third embodiment includes the step S10 of manufacturing the piezoelectric substrate 2 including the vibration element 100, the frame portion 200, and the coupling portion 300, and the step S20 of separating the vibration element 100 from the frame portion 200.

Hereinafter, points different from the example of the method of manufacturing the vibration element 100 according to the first embodiment described above will be described, and description of similar points will be omitted.

### 3.2.2. Piezoelectric Substrate

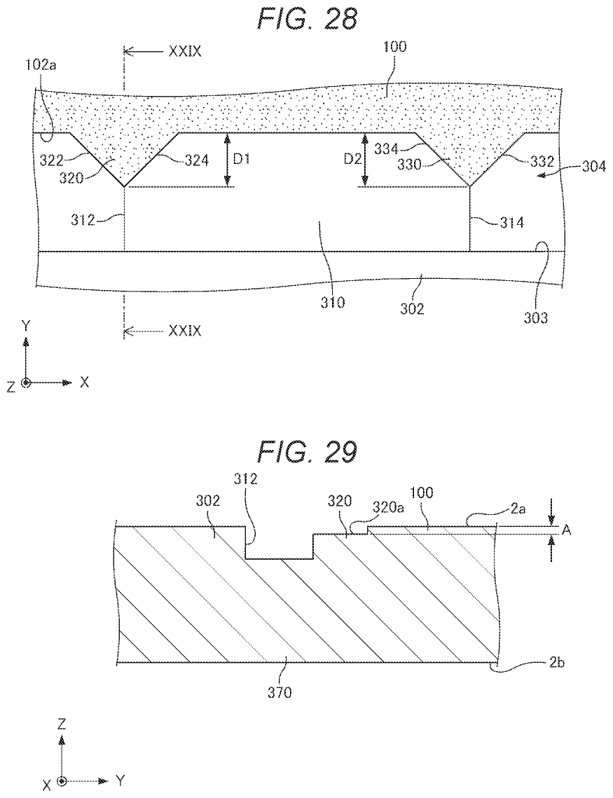

FIG. 28 is a plan view schematically showing the coupling portion 300. FIG. 29 is a cross-sectional view taken along a line XXIX-XXIX in FIG. 28. Hereinafter, in the piezoelectric substrate 2 according to the third embodiment, members having the same functions as the constituent members of the piezoelectric substrate 2 according to the first embodiment and the second embodiment described above are denoted by the same reference numerals, and detailed description thereof is omitted.

In the method of manufacturing the vibration element 100 according to the second embodiment described above, in the step S10, as shown in FIG. 22, the first protruding portion 320, the second protruding portion 330, the first facing protruding portion 340, and the second facing protruding portion 350 are formed on the piezoelectric substrate 2 at the first surface 2a side. On the other hand, in the method of manufacturing the vibration element 100 according to the third embodiment, as shown in FIG. 28, in the step S10, the first protruding portion 320 and the second protruding portion 330 are formed without forming the first facing protruding portion 340 and the second facing protruding portion 350.

The shapes and sizes of the first protruding portion 320 and the second protruding portion 330 are the same as the shapes and sizes of the first protruding portion 320 and the second protruding portion 330 of the vibration element 100 shown in FIG. 22 described above, and the description thereof is omitted.

The first recessed portion 312 is formed between the first protruding portion 320 and the base end portion 302. The first recessed portion 312 is formed between the first protruding portion 320 and the frame portion 200. The first recessed portion 312 is formed from the tip end of the first protruding portion 320 to the base end portion 302.

The second recessed portion 314 is formed between the second protruding portion 330 and the base end portion 302. The second recessed portion 314 is formed between the second protruding portion 330 and the frame portion 200. The second recessed portion 314 is formed from the tip end of the second protruding portion 330 to the base end portion 302.

The first recessed portion 312, the first groove portion 310, and the second recessed portion 314 form one continuous groove. The groove formed by the first recessed portion 312, the first groove portion 310, and the second recessed portion 314 is formed from the end in a −X-axis direction to the end in a +X-axis direction of the breaking portion 304.

The second groove portion 360, the third protruding portion 370, and the fourth protruding portion 380 formed at the second surface 2b side are the same as those of the vibration element 100 according to the first embodiment shown in FIG. 6, and the description thereof is omitted.

### 3.2.3. Step S10 of Manufacturing Piezoelectric Substrate Including Vibration Element, Frame Portion, and Coupling Portion

In the method of manufacturing the vibration element 100 according to the third embodiment, a step S10 is the same as the step S10 in the method of manufacturing the vibration element 100 according to the second embodiment except that the first corrosion-resistant film 4a is patterned such that the first recessed portion 312 and the second recessed portion 314 are formed without forming the first facing protruding portion 340 and the second facing protruding portion 350 in the step of etching the first corrosion-resistant film 4a and the second corrosion-resistant film 4b shown in FIGS. 16 and 17, and the description thereof is omitted.

3.2.4. Step S20 of Separating Vibration Element from Frame Portion

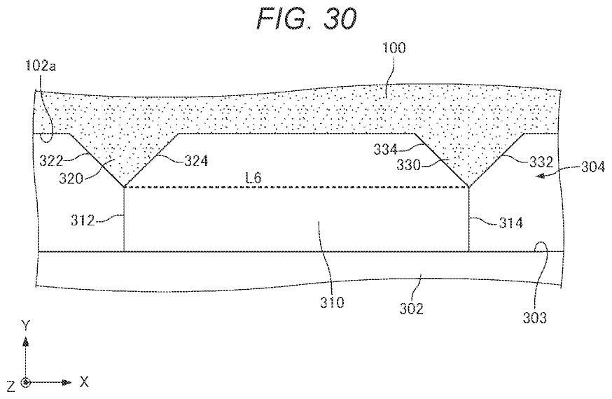

FIG. 30 is a plan view schematically showing the coupling portion 300. In FIG. 30, a broken line indicates a position where the breaking portion 304 breaks.

When the suction nozzle 500 is pushed toward the first surface 2a side of the vibration element 100, as shown in FIG. 30, the breaking portion 304 breaks at a position indicated by a virtual straight line L6 coupling a position adjacent to the tip end of the first protruding portion 320 of the first recessed portion 312 and a position adjacent to the tip end of the second protruding portion 330 of the second recessed portion 314 when viewed from the direction perpendicular to the first surface 2a.

When the vibration element 100 is folded at the coupling portion 300, stress concentrates on the tip end of the first protruding portion 320 and the tip end of the second protruding portion 330. Further, the thickness of the piezoelectric substrate 2 decreases and the strength decreases at a position where the first recessed portion 312 is formed and a position where the second recessed portion 314 is formed. Thereby, a position adjacent to the tip end of the first protruding portion 320 of the first recessed portion 312 serves as a starting point of breakage. Similarly, a position adjacent to the tip end of the second protruding portion 330 of the second recessed portion 314 serves as a starting point of breakage. As a result, the breaking portion 304 breaks at the position indicated by the virtual straight line L6. Accordingly, in the method of manufacturing the vibration element 100 according to the third embodiment, a breaking position when the vibration element 100 is folded at the coupling portion 300 can be constant.

### 3.3. Operation and Effect

The method of manufacturing the vibration element 100 according to the third embodiment can achieve the same effects as those of the method of manufacturing the vibration element 100 according to the second embodiment.

### 3.4. Modification

In the third embodiment described above, a case in which the first protruding portion 320 and the second protruding portion 330 are formed without forming the first facing protruding portion 340 and the second facing protruding portion 350 in the step S10 is described. However, although not shown, the first facing protruding portion 340 and the second facing protruding portion 350 may be formed without forming the first protruding portion 320 and the second protruding portion 330. In this case, when the vibration element 100 is folded at the coupling portion 300 in the step S20, stress can be concentrated on the tip end of the first facing protruding portion 340 and the tip end of the second facing protruding portion 350.

### 4. Modification

The present disclosure is not limited to the embodiments described above, and various modifications can be made within the scope of the gist of the present disclosure.

### (1) First Modification

In the first embodiment described above, in the step S10, the first groove portion 310, the first protruding portion 320, the second protruding portion 330, the first facing protruding portion 340, and the second facing protruding portion 350 are formed on the piezoelectric substrate 2 at the first surface 2a side, and the second groove portion 360, the third protruding portion 370, and the fourth protruding portion 380 are formed on the piezoelectric substrate 2 at the second surface 2b side. When the vibration element 100 is separated from the frame portion 200 in the step S20, the suction nozzle 500 is pushed toward the first surface 2a side of the vibration element 100 to break the vibration element 100 from the first surface 2a side.

On the other hand, in the step S10, the first groove portion 310, the first protruding portion 320, the second protruding portion 330, the first facing protruding portion 340, and the second facing protruding portion 350 may be formed on the piezoelectric substrate 2 at the second surface 2b side, and the second groove portion 360, the third protruding portion 370, and the fourth protruding portion 380 may be formed on the piezoelectric substrate 2 at the first surface 2a side. In this case, when the vibration element 100 is separated from the frame portion 200 in step S20, the suction nozzle 500 may be pushed toward the second surface 2b side of the vibration element 100 to break the vibration element 100 from the second surface 2b side. The same applies to the second embodiment and the third embodiment.

### (2) Second Modification

In the first embodiment described above, as shown in FIG. 6, the second groove portion 360, the third protruding portion 370, and the fourth protruding portion 380 are formed on the piezoelectric substrate 2 at the second surface 2b side, but the second surface 2b side of the piezoelectric substrate 2 may be flat. The same applies to the second embodiment and the third embodiment.

### (3) Third Modification

In the method of manufacturing the vibration element according to the first embodiment described above, the case of manufacturing the tuning fork type piezoelectric vibration element is described, but the method of manufacturing the vibration element according to the first embodiment is not limited to the method of manufacturing the tuning fork type piezoelectric vibration element. For example, the method of manufacturing the vibration element according to the first embodiment can also be applied to a vibration element or the like that is formed of a quartz crystal substrate such as an AT cut quartz crystal substrate or an SC cut quartz crystal substrate and vibrates in a thickness-shear vibration mode. The method of manufacturing the vibration element according to the first embodiment can also be applied to a vibration element other than the tuning fork type piezoelectric vibration element by forming a mask for etching the piezoelectric substrate according to the shape of the vibration element. The same applies to the second embodiment and the third embodiment.

The embodiments and modifications described above are examples, and the present disclosure is not limited thereto. For example, the embodiments and the modifications can be appropriately combined.

The present disclosure is not limited to the embodiments described above, and further various modifications are possible. For example, the present disclosure includes substantially the same configuration as the configuration described in the embodiments. Substantially the same configuration is, for example, a configuration having the same function, method, and result, or a configuration having the same object and effect. The present disclosure has a configuration in which a non-essential portion of the configuration described in the embodiments is replaced. In addition, the present disclosure may have a configuration capable of achieving the same operation and effect or a configuration capable of achieving the same object as the configuration described in the embodiments. The present disclosure has a configuration obtained by adding a known technique to the configuration described in the embodiments.

The following contents are derived from the embodiments and modifications described above.

A method of manufacturing a vibration element according to an aspect includes:
manufacturing, by wet etching, a piezoelectric substrate including a vibration element, a frame portion, and a coupling portion that couples the frame portion and the vibration element; and
folding the vibration element at the coupling portion and separating the vibration element from the frame portion, in which
in the manufacturing of the piezoelectric substrate by the wet etching,
the coupling portion is formed with a first groove portion, and a first protruding portion and a second protruding portion at one surface of a first surface and a second surface which is in a front and rear relationship with the first surface, the first protruding portion and the second protruding portion being disposed at positions sandwiching the first groove portion and protruding from an outer shape side of the vibration element to which the coupling portion is coupled when viewed from a direction perpendicular to the one surface,
when viewed from the direction perpendicular to the one surface, the first protruding portion has a first outer shape side that defines an outer shape of the coupling portion and a second outer shape side that defines a boundary between the first protruding portion and the first groove portion, and is formed in a shape in which a distance between the first outer shape side and the second outer shape side decreases as a distance from the outer shape side of the vibration element to which the coupling portion is coupled increases, and the first outer shape side and the second outer shape side are formed to be inclined with respect to the outer shape side of the vibration element to which the coupling portion is coupled, and
when viewed from the direction perpendicular to the one surface, the second protruding portion has a third outer shape side that defines the outer shape of the coupling portion and a fourth outer shape side that defines a boundary between the second protruding portion and the first groove portion, and is formed in a shape in which a distance between the third outer shape side and the fourth outer shape side decreases as a distance from the outer shape side of the vibration element to which the coupling portion is coupled increases, and the third outer shape side and the fourth outer shape side are formed to be inclined with respect to the outer shape side of the vibration element to which the coupling portion is coupled.

According to the method of manufacturing a vibration element, when the vibration element is folded at the coupling portion and separated from the frame portion, stress concentrates on a tip end of the first protruding portion and a tip end of the second protruding portion. Accordingly, in the method of manufacturing a vibration element, a breaking position when the vibration element is folded at the coupling portion can be constant. As a result, a remaining portion of the coupling portion remaining in the vibration element after the vibration element is separated from the frame portion can be made small.

In the above method of manufacturing a vibration element according to an aspect,
in the manufacturing of the piezoelectric substrate by the wet etching,
when viewed from the direction perpendicular to the one surface, the vibration element may be formed with a second side and a third side, which are the outer shape side of the vibration element located in a protruding direction of the first protruding portion with respect to the first side and which sandwich a first side which is the outer shape side of the vibration element to which the coupling portion is coupled,
in the protruding direction of the first protruding portion, a distance between a tip end of the first protruding portion and the first side may be formed to be smaller than a distance between the first side and the second side and a distance between the first side and the third side, and
in a protruding direction of the second protruding portion, a distance between a tip end of the second protruding portion and the first side may be formed to be smaller than the distance between the first side and the second side and the distance between the first side and the third side.

According to the method of manufacturing a vibration element, a length by which the remaining portion of the coupling portion protrudes from the second side and the third side can be reduced, and the remaining portion can be prevented from protruding from the second side and the third side.

In the above method of manufacturing a vibration element according to an aspect,
in the manufacturing of the piezoelectric substrate by the wet etching,
the first outer shape side and the second outer shape side may be formed to intersect with each other at a tip end of the first protruding portion,
the third outer shape side and the fourth outer shape side may be formed to intersect with each other at a tip end of the second protruding portion,
a first recessed portion continuous with the first groove portion may be formed between the first protruding portion and the frame portion, and
a second recessed portion continuous with the first groove portion may be formed between the second protruding portion and the frame portion.

According to the method of manufacturing a vibration element, a breaking position when the vibration element is folded at the coupling portion can be constant.

In the above method of manufacturing a vibration element according to an aspect,
in the manufacturing of the piezoelectric substrate by the wet etching,
the coupling portion may be formed with a second groove portion, and a third protruding portion and a fourth protruding portion at the other surface of the first surface and the second surface, the third protruding portion and the fourth protruding portion being disposed at positions sandwiching the second groove portion and protruding from the outer shape side of the vibration element to which the coupling portion is coupled when viewed from a direction perpendicular to the other surface, and
it may be that W1+W2<W3+W4, and W5>W6 are satisfied, where W1 is a maximum width of the first protruding portion, W2 is a maximum width of the second protruding portion, W3 is a maximum width of the third protruding portion, W4 is a maximum width of the fourth protruding portion, a maximum width of the first groove portion is W5, and W6 is a maximum width of the second groove portion.

According to the method of manufacturing a vibration element, when the vibration element is folded at the coupling portion, the vibration element can be easily broken from the one surface of the coupling portion.

What is claimed is:

1. A method of manufacturing a vibration element, the method comprising:
manufacturing, by wet etching, a piezoelectric substrate including a vibration element, a frame portion, and a coupling portion that couples the frame portion and the vibration element; and
folding the vibration element at the coupling portion and separating the vibration element from the frame portion, wherein
in the manufacturing of the piezoelectric substrate by the wet etching,
the coupling portion is formed with a first groove portion, and a first protruding portion and a second protruding portion at one surface of a first surface and a second surface which is in a front and rear relationship with the first surface, the first protruding portion and the second protruding portion being disposed at positions sandwiching the first groove portion and protruding from an outer shape side of the vibration element to which the coupling portion is coupled when viewed from a direction perpendicular to the one surface,
when viewed from the direction perpendicular to the one surface, the first protruding portion has a first outer shape side that defines an outer shape of the coupling portion and a second outer shape side that defines a boundary between the first protruding portion and the first groove portion, and is formed in a shape in which a distance between the first outer shape side and the second outer shape side decreases as a distance from the outer shape side of the vibration element to which the coupling portion is coupled increases, and the first outer shape side and the second outer shape side are formed to be inclined with respect to the outer shape side of the vibration element to which the coupling portion is coupled, and
when viewed from the direction perpendicular to the one surface, the second protruding portion has a third outer shape side that defines the outer shape of the coupling portion and a fourth outer shape side that defines a boundary between the second protruding portion and the first groove portion, and is formed in a shape in which a distance between the third outer shape side and the fourth outer shape side decreases as a distance from the outer shape side of the vibration element to which the coupling portion is coupled increases, and the third outer shape side and the fourth outer shape side are formed to be inclined with respect to the outer shape side of the vibration element to which the coupling portion is coupled.

2. The method of manufacturing a vibration element according to claim 1, wherein
in the manufacturing of the piezoelectric substrate by the wet etching,
when viewed from the direction perpendicular to the one surface, the vibration element is formed with a second side and a third side, which are the outer shape side of the vibration element located in a protruding direction of the first protruding portion with respect to the first side and which sandwich a first side which is the outer shape side of the vibration element to which the coupling portion is coupled,
in the protruding direction of the first protruding portion, a distance between a tip end of the first protruding portion and the first side is formed to be smaller than a distance between the first side and the second side and a distance between the first side and the third side, and
in a protruding direction of the second protruding portion, a distance between a tip end of the second protruding portion and the first side is formed to be smaller than the distance between the first side and the second side and the distance between the first side and the third side.

3. The method of manufacturing a vibration element according to claim 1, wherein
in the manufacturing of the piezoelectric substrate by the wet etching,
the first outer shape side and the second outer shape side are formed to intersect with each other at a tip end of the first protruding portion,
the third outer shape side and the fourth outer shape side are formed to intersect with each other at a tip end of the second protruding portion,
a first recessed portion continuous with the first groove portion is formed between the first protruding portion and the frame portion, and
a second recessed portion continuous with the first groove portion is formed between the second protruding portion and the frame portion.

4. The method of manufacturing a vibration element according to claim 1, wherein
in the manufacturing of the piezoelectric substrate by the wet etching,
the coupling portion is formed with a second groove portion, and a third protruding portion and a fourth protruding portion at the other surface of the first surface and the second surface, the third protruding portion and the fourth protruding portion being disposed at positions sandwiching the second groove portion and protruding from the outer shape side of the vibration element to which the coupling portion is coupled when viewed from a direction perpendicular to the other surface, and
W1+W2<W3+W4, and W5>W6 are satisfied, where W1 is a maximum width of the first protruding portion, W2 is a maximum width of the second protruding portion, W3 is a maximum width of the third protruding portion, W4 is a maximum width of the fourth protruding portion, a maximum width of the first groove portion is W5, and W6 is a maximum width of the second groove portion.
